(19) United States
(12) Patent Application Publication
(10) Pub. No.: US 2012/0068289 A1
(43) Pub. Date: Mar. 22, 2012

(54) Devices Having Enhanced Electromagnetic Radiation Detection and Associated Methods

(75) Inventors: Susan Alie, Stoneham, MA (US); Martin U. Pralle, Wayland, MA (US); Chintamani Palsule, Lake Oswego, OR (US); Jeffrey McKee, Tualatin, OR (US); Xia Li, Beverly, MA (US)

(73) Assignee: SIONYX, INC., Beverly, MA (US)

(21) Appl. No.: 13/069,135

(22) Filed: Mar. 22, 2011

Related U.S. Application Data
(60) Provisional application No. 61/317,147, filed on Mar. 24, 2010.

(51) Int. Cl. H01L 31/0232; H01L 21/31

(52) U.S. Cl. 257/432; 438/455; 257/E31.127; 257/E21.24

(57) ABSTRACT

Photosensitive semiconductor devices and associated methods are provided. In one aspect, a semiconductor device can include a semiconductor substrate and a semiconductor layer coupled to the semiconductor substrate, where the semiconductor layer has a device surface opposite the semiconductor substrate. The device also includes at least one textured region coupled between the semiconductor substrate and the semiconductor layer. In another aspect, the device further includes at least one dielectric layer coupled between the semiconductor substrate and the semiconductor layer.

### PRIORITY DATA

This application claims the benefit of U.S. Provisional Patent Application Ser. No. 61/317,147, filed on Mar. 24, 2010, which is incorporated herein by reference.

### BACKGROUND

Semiconductor on Insulator (SOI) wafer technology is an outgrowth of MicroElectroMechanical Systems (MEMS) technologies. An SOI wafer is a stacked wafer substrate where a device wafer (typically silicon) is bonded to a dielectric layer that is bonded to a support wafer, otherwise known as a handle wafer. A typical process flow for the fabrication of SOI wafers can be as follows: two wafers are polished and coated with an oxide or other dielectric material. The wafers are mounted polished side face to face and bonded under high temperature and pressure. Then one of the two wafers is ground down using mechanical grinding and chemical mechanical polishing to a specific thickness. In this way it is possible to generate semiconductor wafers that are electrically isolated from the underlying substrate.

### SUMMARY

The present disclosure provides semiconductor structures and devices that can exhibit various enhanced properties, such as, for example, enhanced light detection properties. In one aspect, a semiconductor device is provided. Such a device can include a semiconductor substrate and a semiconductor layer coupled to the semiconductor substrate, where the semiconductor layer has a device surface opposite the semiconductor substrate. The device also includes at least one textured region coupled between the semiconductor substrate and the semiconductor layer. In another aspect, the device further includes at least one dielectric layer coupled between the semiconductor substrate and the semiconductor layer. In one aspect, the semiconductor layer is an epitaxially grown semiconductor layer. In another aspect, the semiconductor layer is a silicon layer. In a further aspect, a secondary semiconductor layer is disposed between the textured region and the semiconductor layer.

Various positional configurations for the layers according to aspects of the present disclosure are contemplated, and any such configuration is considered to be within the present scope. In one specific aspect, for example, the dielectric layer is coupled between the semiconductor substrate and the textured region, and the textured region is disposed between the dielectric layer and the semiconductor layer. In one specific aspect, a reflective region is disposed between the semiconductor substrate and the textured region. In another specific aspect, the textured region is coupled directly to the semiconductor layer. In yet another specific aspect, a secondary semiconductor layer is disposed between the textured region and the semiconductor layer. In a further specific aspect, at least one cavity region disposed between the textured region and the dielectric layer. As another aspect of positional arrangement, the textured region is disposed between the semiconductor substrate and the dielectric layer, and the dielectric layer is disposed between the textured region and the semiconductor layer.

In one aspect of the present disclosure, a polysilicon layer is directly coupled to the dielectric layer. In another aspect, the polysilicon layer is disposed between multiple dielectric layers. In some aspects, the polysilicon layer can be doped.

In one aspect of the present disclosure, at least one photodiode optically active region is disposed on the device surface. In another aspect, the photodiode optically active region comprises a doped region. In yet another aspect, the device forms at least one photodetector. In a further aspect, the at least one photodetector is a plurality of photodetectors arranged in an array. In yet a further aspect, the textured region is arranged in a discontinuous pattern that corresponds spatially to the array of photodetectors. In another aspect, the device includes a plurality of isolation features in at least the semiconductor layer to isolate each photodetector in the array of photo detectors, where the isolation features isolate each photodetector electrically, optically, or both electrically and optically. In yet another aspect, the device includes at least one optical lens associated with the at least one photodetector. In a further aspect, the device includes at least one color filter associated with the at least one photodetector.

In one aspect of the present disclosure, the textured region is doped with a dopant to form an electrical back surface field. In another aspect, the electrical back surface field has been doped by a technique such as, without limitation, laser doping, ion implanting, diffusion doping, in situ doping, and the like, including combinations thereof. In yet another aspect, the textured region has a higher dopant concentration than the semiconductor layer. In a further aspect, the dopant has the same polarity as the semiconductor layer. Non-limiting examples of such dopants can include boron, indium, gallium, arsenic, antimony, phosphorus, and the like, including combinations thereof. Additionally, in other aspects a back surface field can be created by doping the semiconductor layer outside of the textured region. In one aspect, for example, the semiconductor layer is doped with a dopant to form an electrical back surface field, where the electrical back surface field is distinct from the textured region.

The present disclosure additionally provides methods of making semiconductor devices. In one aspect, one such method includes texturing at least a portion of a surface of a semiconductor layer to form a textured region, depositing a first dielectric layer onto the semiconductor layer such that the textured region is disposed between the semiconductor layer and the first dielectric layer, and wafer bonding the first dielectric layer to a second dielectric layer disposed on a semiconductor substrate. In one aspect, the semiconductor layer is an epitaxially grown semiconductor layer. In another aspect, texturing at least a portion of a surface of a semiconductor layer to form a textured region further includes forming the epitaxially grown semiconductor layer on a growth substrate and texturing at least a portion of a surface of the epitaxially grown semiconductor layer to form a textured region. In yet another aspect, the method includes removing the growth substrate to expose the epitaxially grown semiconductor layer. In an alternative aspect, the method can include forming an epitaxially grown semiconductor layer on the semiconductor layer on an opposite side from the textured region.

In another aspect, wafer bonding includes depositing a polysilicon layer on the first dielectric layer and then bonding the polysilicon layer between the first dielectric layer and the second dielectric layer. In yet another aspect, at least a portion of the polysilicon layer can be doped. It is also contemplated that the present scope can include multiple dielectric and/or semiconductor material layers disposed between the semiconductor substrate and semiconductor layer.

In a further aspect, texturing at least a portion of a surface of the semiconductor layer to form the textured region further includes forming an opening in the semiconductor substrate, the second dielectric layer, and the first dielectric layer to expose a portion of the semiconductor layer and texturing at least a portion of the exposed portion of the semiconductor layer to form the textured region.

In another aspect, the present disclosure provides a method of protecting a textured region from contamination during manufacture of a semiconductor device. Such a method includes texturing at least a portion of a surface of a semiconductor layer to form a textured region, depositing a first dielectric layer onto the semiconductor layer such that the textured region is disposed between the semiconductor layer and the dielectric layer, and wafer bonding the first dielectric layer to a second dielectric layer disposed on a semiconductor substrate, wherein the textured region is protected from contamination during further manufacturing processes by the semiconductor layer and the semiconductor substrate.

### BRIEF DESCRIPTION OF THE DRAWINGS

For a further understanding of the nature and advantage of the present disclosure, reference is being made to the following detailed description of embodiments and in connection with the accompanying drawings, in which:

FIG. 1 is a cross-sectional view of a semiconductor structure in accordance with an embodiment of the present disclosure;

FIG. 2A is a cross-sectional view of a semiconductor structure in accordance with another embodiment of the present disclosure;

FIG. 2B is a cross-sectional view of a semiconductor structure in accordance with another embodiment of the present disclosure;

FIG. 2C is a cross-sectional view of a semiconductor structure in accordance with another embodiment of the present disclosure;

FIG. 2D is a cross-sectional view of a semiconductor structure in accordance with another embodiment of the present disclosure;

FIG. 3 is a cross-sectional view of a semiconductor structure in accordance with another embodiment of the present disclosure;

FIG. 4 is a cross-sectional view of a semiconductor structure in accordance with another embodiment of the present disclosure;

FIG. 5 is a cross-sectional view of a semiconductor photodiode in accordance with another embodiment of the present disclosure;

FIG. 6 is a cross-sectional view of a semiconductor photodetecting imager in accordance with another embodiment of the present disclosure;

FIG. 7 is a cross-sectional view of a semiconductor structure in accordance with another embodiment of the present disclosure;

FIG. 8 is a cross-sectional view of a semiconductor structure in accordance with another embodiment of the present disclosure;

FIG. 9 is a cross-sectional view of a semiconductor structure in accordance with another embodiment of the present disclosure;

FIG. 10 is a cross-sectional view of a semiconductor structure in accordance with another embodiment of the present disclosure;

FIG. 11A is a cross-sectional view of a semiconductor structure showing the manufacture of a semiconductor device in accordance with another embodiment of the present disclosure;

FIG. 11B is a cross-sectional view of a semiconductor structure showing the manufacture of a semiconductor device in accordance with another embodiment of the present disclosure;

FIG. 11C is a cross-sectional view of a semiconductor structure showing the manufacture of a semiconductor device in accordance with another embodiment of the present disclosure;

FIG. 12A is a cross-sectional view of a semiconductor structure showing the manufacture of a semiconductor device in accordance with another embodiment of the present disclosure;

FIG. 12B is a cross-sectional view of a semiconductor structure showing the manufacture of a semiconductor device in accordance with another embodiment of the present disclosure;

FIG. 12C is a cross-sectional view of a semiconductor structure showing the manufacture of a semiconductor device in accordance with another embodiment of the present disclosure;

FIG. 13A is a cross-sectional view of a semiconductor structure showing the manufacture of a semiconductor device in accordance with another embodiment of the present disclosure;

FIG. 13B is a cross-sectional view of a semiconductor structure showing the manufacture of a semiconductor device in accordance with another embodiment of the present disclosure;

FIG. 13C is a cross-sectional view of a semiconductor structure showing the manufacture of a semiconductor device in accordance with another embodiment of the present disclosure;

FIG. 13D is a cross-sectional view of a semiconductor structure showing the manufacture of a semiconductor device in accordance with another embodiment of the present disclosure; and

FIG. 14 is a depiction of a method of making a semiconductor device in accordance with yet another aspect of the present disclosure.

### DETAILED DESCRIPTION

Before the present disclosure is described herein, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

Definitions

The following terminology will be used in accordance with the definitions set forth below.

It should be noted that, as used in this specification and the appended claims, the singular forms “a,” and, “the” include plural referents unless the context clearly dictates otherwise. Thus, for example, reference to “a dopant” includes one or more of such dopants and reference to “the layer” includes reference to one or more of such layers.

As used herein, the terms “disordered surface” and “textured surface” can be used interchangeably, and refer to a surface having a topology with nano- to micron-sized surface variations. Although any texturing technique is considered to be within the present scope, in one aspect the texturing is formed by the irradiation of laser pulses. Furthermore, while the characteristics of a textured surface can be variable depending on the materials and techniques employed, in one aspect such a surface can be several hundred nanometers thick and made up of nanocrystallites (e.g. from about 10 to about 50 nanometers), nanopores, and the like. In another aspect, such a surface can include micron-sized structures (e.g. about 2 μm to about 60 μm). In yet another aspect, the surface can include nano-sized and/or micron-sized structures from about 5 nm and about 500 μm.

As used herein, the terms “surface modifying,” “surface modification,” and “texturing” can be used interchangeably, and refer to the altering of a surface of a semiconductor material using a texturing technique. In one specific aspect, surface modification can include processes using primarily laser radiation or laser radiation in combination with a dopant, whereby the laser radiation facilitates the incorporation of the dopant into a surface of the semiconductor material. Accordingly, in one aspect surface modification includes doping the material.

As used herein, the term “fluence” refers to the amount of energy from a single pulse of laser radiation that passes through a unit area. In other words, “fluence” can be described as the energy density of one laser pulse.

As used herein, the term “target region” refers to an area of a semiconductor material that is intended to be doped or surface modified using laser radiation. The target region of a semiconductor material can vary as the surface modifying process progresses. For example, after a first target region is doped or surface modified, a second target region may be selected on the same semiconductor material.

As used herein, the term “absorptance” refers to the fraction of incident electromagnetic radiation absorbed by a material or device.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

The Disclosure

The present disclosure provides semiconductor devices and associated methods that can exhibit various enhanced properties, such as, for example, enhanced light detection properties. Additionally, the present disclosure provides an integrated approach for the fabrication and application of textured semiconductor materials resulting in enhancement of image sensors and photodetectors. Specific types of semiconductor texturing can enhance the spectral bandwidth, absorption, and quantum efficiency of a semiconductor material. Performance can also be enhanced through various architecture configurations. Such configurations can also significantly improve the process integration of a particular device architecture with traditional process flows such as, for example, traditional CMOS process flows.

A device design having a textured region located on, for example, the back surface of a photodetector, provides significant performance benefits. The textured region can have surface features that can lead to higher recombination of photocarriers for short wavelengths (e.g. in the blue green part of the spectrum) due to the very shallow penetration of those wavelengths into the detecting volume of the device. By physically locating the textured on the back surface of the device, a pristine surface is provided for the collection of short wavelengths on the top surface (i.e. the light incident surface), and the longer wavelengths that penetrate deep into or through the detecting region of the semiconductor material are collected by or with the help of the textured region opposite the light incident surface. It should be noted that, in addition to backside illuminated, front side illuminated architectures are also contemplated to be within the present scope. In addition, enhanced performance and ease of manufacture can also be accomplished by locating a textured region within a semiconductor stack or wafer. In some aspects, the textured layer can be located within the semiconductor stack early in the manufacturing process prior to the deposition of structures or circuitry that may be negatively affected by a texturing process. Additionally, such a semiconductor stack can be sent to an outside fabrication process for further manufacturing without exposing technological details regarding the textured region embedded between the semiconductor layers or any interaction between the textured region and the semiconductor layers.

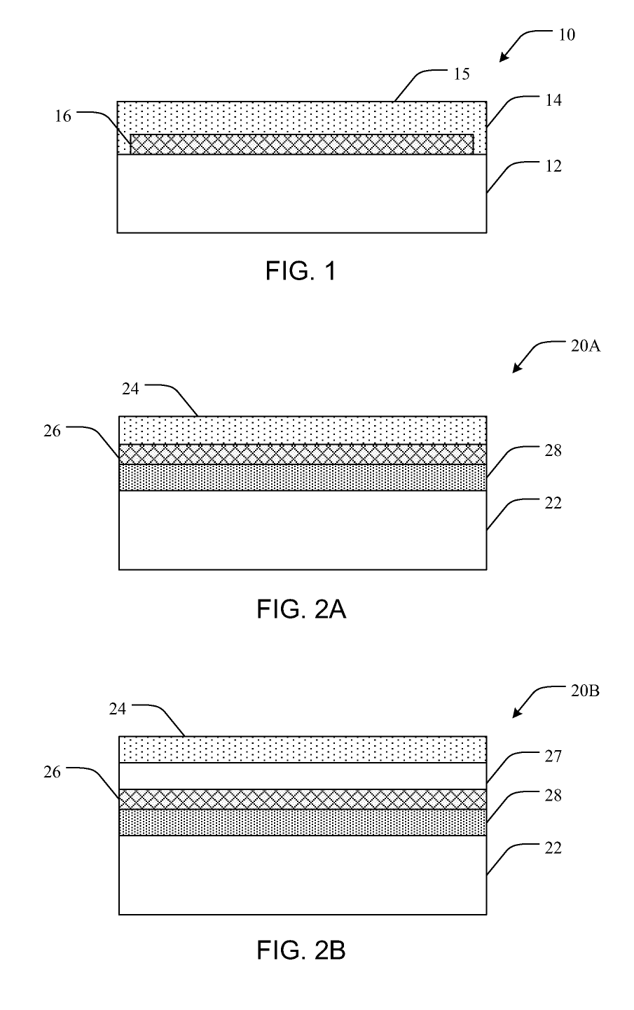

In one aspect, as is shown in FIG. 1, a semiconductor device 10 is provided. While various semiconductor functions are contemplated, in one aspect the semiconductor device can exhibit enhanced electromagnetic radiation detection. Such a device can include a semiconductor substrate 12 and a semiconductor layer 14 coupled to the semiconductor substrate. The semiconductor layer has a device surface 15 opposite the semiconductor substrate. The device also includes at least one textured region 16 located or coupled between the semiconductor substrate and the semiconductor layer. As such, the textured region is enclosed between the semiconductor substrate and the semiconductor layer. Subsequent processing of the semiconductor device such as, for example, the formation of structures on the device surface, does not affect this buried textured region. In one aspect, the textured region can be formed on the semiconductor substrate. In another aspect, the textured region can be formed on the semiconductor layer. Additionally, for FIG. 1 and subsequent figures, the textured region can be a single textured region as is shown, or the textured region can be multiple discrete textured regions. Also, the textured region can cover only a portion of the surface area between the semiconductor substrate and the semiconductor layer as is shown, or the textured region can cover the entire surface area there between.

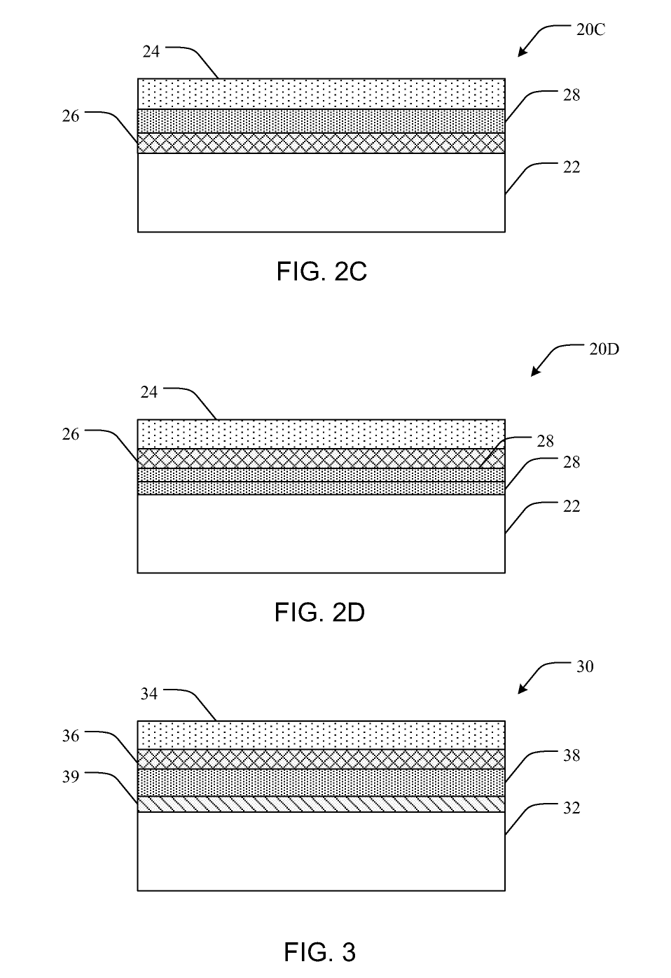

In another aspect, as is shown in FIG. 2A, a semiconductor device 20A is provided. Such a device can include a semiconductor substrate 22 and a semiconductor layer 24 coupled to the semiconductor substrate. The device also includes at least one textured region 26 located or coupled between the semiconductor substrate and the semiconductor layer, and at least one dielectric layer 28 coupled between the semiconductor substrate and the semiconductor layer. While various utilities are contemplated for the dielectric layer, in one aspect such a layer can be used to wafer bond the semiconductor layer to the semiconductor substrate. In one aspect, the dielectric layer can be formed on the semiconductor substrate. In another aspect, the dielectric layer can be formed on the textured region. Also, in some aspects the textured region can be formed on the dielectric layer. Additionally, in one aspect the semiconductor layer can be an epitaxially grown semiconductor layer. Thus in some aspects, the textured region can be formed on the epitaxially grown semiconductor layer.

It should be noted that, for all aspects, the present scope can also include multiple dielectric layers and/or multiple semiconductor material layers disposed between the semiconductor substrate and semiconductor layer. Additionally, the semiconductor layer itself can be multiple semiconductor layers and the semiconductor substrate can include multiple layers. It should also be noted that the semiconductor substrate refers to a substrate for a semiconductor, and can be comprised of semiconductor materials and/or non-semiconductor materials.

FIG. 2B shows a semiconductor device 20B having a secondary semiconductor layer 27 located between the textured region and the semiconductor layer. A semiconductor layer 24 is formed on the secondary semiconductor layer. In one aspect the semiconductor layer is an epitaxially grown semiconductor layer. Thus in some aspects, the textured region can be formed on the secondary semiconductor layer or on the dielectric layer 28. It should be noted that all reference numbers in FIGS. 2B-D that have been reused from FIG. 2A denote the same or similar materials and/or structures whether or not further description is provided.

FIG. 2C shows a semiconductor device 20C whereby the dielectric layer 28 coupled between the semiconductor layer and the textured region. In this case, the dielectric layer can be formed on the semiconductor layer 24, the textured region 28, or on both the semiconductor layer and the textured region. In one aspect, the textured region can be formed on the semiconductor substrate 22. In another aspect, the textured region can be formed on the dielectric layer.

Additionally, in some aspects, as is shown in FIG. 2D for semiconductor device 20D, the dielectric layer can be a plurality of dielectric layers 28. In the case of wafer bonding, for example, a first dielectric layer can be associated with the textured layer and a second dielectric layer can be associated with the semiconductor substrate. The first dielectric layer and the second dielectric layer are heated and pressed together, with or without the aid of further pressure, temperature, or plasma surface activation, to cause the dielectric layers to bond to one another, thus forming a single wafer-bonded structure. It should be noted, however, that wafer-bonding can be accomplished without one or more dielectric layers, and as such the present scope should also include wafer-bonding that lacks such dielectric materials. Additionally, in some aspects, the textured region can be located in between the plurality of dielectric layers (not shown).

A variety of semiconductor materials are contemplated for use with the devices and methods according to aspects of the present disclosure. Such materials can be utilized as the semiconductor layer and/or the semiconductor substrate, as well as for the secondary semiconductor layer and the epitaxially grown semiconductor layer. Non-limiting examples of such semiconductor materials can include group IV materials, compounds and alloys comprised of materials from groups II and VI, compounds and alloys comprised of materials from groups III and V, and combinations thereof. More specifically, exemplary group IV materials can include silicon, carbon (e.g. diamond), germanium, and combinations thereof. Various exemplary combinations of group IV materials can include silicon carbide (SiC) and silicon germanium (SiGe). In one specific aspect, the semiconductor material can be or include silicon. Exemplary silicon materials can include amorphous silicon (a-Si), microcrystalline silicon, multicrystalline silicon, and monocrystalline silicon, as well as other crystal types. In another aspect, the semiconductor material can include at least one of silicon, carbon, germanium, aluminum nitride, gallium nitride, indium gallium arsenide, aluminum gallium arsenide, and combinations thereof.

Exemplary combinations of group II-VI materials can include cadmium selenide (CdSe), cadmium sulfide (CdS), cadmium telluride (CdTe), zinc oxide (ZnO), zinc selenide (ZnSe), zinc sulfide (ZnS), zinc telluride (ZnTe), cadmium zinc telluride (CdZnTe, CZT), mercury cadmium telluride (HgCdTe), mercury zinc telluride (HgZnTe), mercury zinc selenide (HgZnSe), and combinations thereof.

Exemplary combinations of group III-V materials can include aluminum antimonide (AlSb), aluminum arsenide (AlAs), aluminum nitride (AlN), aluminum phosphide (AlP), boron nitride (BN), boron phosphide (BP), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), indium phosphide (InP), aluminum gallium arsenide (AlGaAs, AlₓGa₁₋ₓAs), indium gallium arsenide (InGaAs, InₓGa₁₋ₓAs), indium gallium phosphide (InGaP), aluminum indium arsenide (AlInAs), aluminum indium antimonide (AlInSb), gallium arsenide nitride (GaAsN), gallium arsenide phosphide (GaAsP), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), aluminum indium arsenide phosphide (AlInAsP), aluminum gallium arsenide nitride (AlGaAsN), indium gallium arsenide nitride (InGaAsN), indium aluminum arsenide nitride (InAlAsN), gallium arsenide antimonide nitride (GaAsSbN), gallium indium nitride arsenide antimonide (GaInNAsSb), gallium indium arsenide antimonide phosphide (GaInAsSbP), and combinations thereof.

The semiconductor material can be of any thickness that allows the desired property or functionality of the semiconductor device, and thus any such thickness of semiconductor material is considered to be within the present scope. The textured region can increase the efficiency of the device such that, in some aspects, the semiconductor material can be thinner than has previously been possible. Decreasing the thickness reduces the amount of semiconductor material used to make such a device. In one aspect, for example, a semiconductor material such as the semiconductor layer has a thickness of from about 500 nm to about 50 μm. In another aspect, the semiconductor material has a thickness of less than or equal to about 500 μm. In yet another aspect, the semiconductor material has a thickness of from about 1 μm to about 10 μm. In a further aspect, the semiconductor material can have a thickness of from about 5 μm to about 750 μm. In yet a further aspect, the semiconductor material can have a thickness of from about 5 μm to about 100 μm.

Additionally, various configurations of semiconductor materials are contemplated, and any such material configuration that can be incorporated into a semiconductor device is considered to be within the present scope. In one aspect, for example, the semiconductor material can include monocrystalline materials. In another aspect, the semiconductor material can include multicrystalline materials. In yet another aspect, the semiconductor material can include microcrystalline materials. It is also contemplated that the semiconductor material can include amorphous materials.

As has been described, the semiconductor substrate can be of any size, shape, and material capable of supporting the semiconductor layer and associated components during manufacture and/or use. The semiconductor substrate can be made from various materials, including the semiconductor materials described above, as well as non-semiconductor materials. Non-limiting examples of such materials can include metals, polymeric materials, ceramics, glass, and the like. In some aspects, the semiconductor substrate and the semiconductor layer have the same or substantially the same thermal expansion properties.

Furthermore, the semiconductor material according to aspects of the present disclosure can comprise multiple layers. In some aspects, layers can vary in majority carrier polarity (i.e. donor or acceptor impurities). The donor or acceptor impurities are typically determined by the type of dopant/impurities introduced into the device either through a growth process, deposition process, epitaxial process, implant process, lasing process or other known process to those skilled in the art. In some aspects such semiconductor materials can include an n-type layer, an intrinsic (i-type) layer, and a p-type layer, thus forming a p-i-n semiconductor material stack that creates a junction and/or depletion region. A semiconductor material devoid of an i-type layer is also contemplated in accordance with the present disclosure. In other aspects the semiconductor material may include multiple junctions. Additionally, in some aspects, variations of n(−−), n(−), n(+), n(++), p(−−), p(−), p(+), or p(++) type semiconductor layers can be used. The minus and positive signs are indicators of the relative magnitude of the doping of the semiconductor material.

As has been described, the textured region is buried between the semiconductor substrate and the semiconductor layer in various architectural arrangements. The textured can be of various thicknesses, depending on the desired use of the material. In one aspect, for example, the textured region has a thickness of from about 500 nm to about 100 μm. In another aspect, the textured region has a thickness of from about 500 nm to about 15 μm. In yet another aspect, the textured region has a thickness of from about 500 nm to about 2 μm. In a further aspect, the textured region has a thickness of from about 500 nm to about 1 μm. In another aspect, the textured region has a thickness of from about 200 nm to about 2 μm.

The textured region can function to diffuse electromagnetic radiation, to redirect electromagnetic radiation, and/or to absorb electromagnetic radiation, thus increasing the quantum efficiency of the device. The textured region can include surface features to further increase the effective absorption length of the device. Non-limiting examples of shapes and configurations of surface features include cones, pillars, pyramids, micolenses, quantum dots, inverted features, gratings, protrusions, sphere-like structures, and the like, including combinations thereof. Additionally, surface features can be micron-sized, nano-sized, or a combination thereof. For example, cones, pyramids, protrusions, and the like can have an average height within this range. In one aspect, the average height would be from the base of the feature to the distal tip of the feature. In another aspect, the average height would be from the surface plane upon which the feature was created to the distal tips of the feature. In one specific aspect, a feature (e.g. a cone) can have a height of from about 50 nm to about 2 μm. As another example, quantum dots, microlenses, and the like can have an average diameter within the micron-sized and/or nano-sized range.

In addition to or instead of surface features, the textured region can include a textured layer. In one aspect, for example, the textured region can include a substantially conformal textured layer. Such a textured layer can have an average thickness of from about 1 nm to about 20 μm. In those aspects where the textured region includes surface features, the conformal textured layer can have a varying thickness relative to the location on the surface features upon which is deposited. In the case of cones, for example, the conformal textured layer can become thinner toward the tips of the cones. Such a conformal layer can include various materials, including, without limitation, SiO₂, Si₃N₄, amorphous silicon, polysilicon, a metal or metals, and the like, including combinations thereof. The conformal textured layer can also be one or more layers of the same or different materials, and can be formed during the creation of surface features or in a separate process.

Textured regions according to aspects of the present disclosure can allow a photosensitive device to experience multiple passes of incident electromagnetic radiation within the device, particularly at longer wavelengths (i.e. infrared). Such internal reflection increases the effective absorption length to be greater than the thickness of the semiconductor layer. This increase in absorption length increases the quantum efficiency of the device, leading to an improved signal to noise ratio.

The materials used for making the textured region can vary depending on the design and the desired characteristics of the device. As such, any material that can be utilized in the construction of a textured region is considered to be within the present scope. In one aspect, for example, the texture region can be a textured portion of a specific material, such as a portion of the semiconductor layer or the semiconductor substrate. If the texture layer is to be associated with the semiconductor layer, for example, a surface facing the semiconductor substrate can be textured prior to an attachment process such as wafer bonding. In another aspect, the textured region can be formed from a material that is deposited onto the semiconductor layer or semiconductor substrate, or the textured layer itself can be deposited. Such materials can include a semiconductor material, a dielectric material, or the like, including combinations thereof. In one specific example, the deposited material can include a silicon material. In another specific example, the deposited material can be polysilicon. In yet another aspect, the deposited material can be a dielectric material.

The texturing process can texture the entire substrate to be processed or only a portion of the substrate. In one aspect, for example, a substrate such as the semiconductor layer can be textured and patterned by an appropriate technique over an entire surface to form the texture region. In another aspect, a substrate such as the semiconductor layer can be textured and patterned across only a portion of a surface by using a selective etching technique, such as a mask, photolithography, and an etch or a laser process to define a specific structure or pattern.

In addition to surface features, the textured region can have a surface morphology that is designed to focus or otherwise direct electromagnetic radiation. For example, in one aspect the textured region has a surface morphology operable to direct electromagnetic radiation into the semiconductor layer. Non-limiting examples of various surface morphologies include sloping, pyramidal, inverted pyramidal, spherical, square, rectangular, parabolic, asymmetric, symmetric, and the like, including combinations thereof.

The textured region, including surface features as well as surface morphologies, can be formed by various techniques, including plasma etching, reactive ion etching, porous silicon etching, lasing, chemical etching (e.g. anisotropic etching, isotropic etching), nanoimprinting, material deposition, selective epitaxial growth, and the like.

One effective method of producing a textured region is through laser processing. Such laser processing allows discrete target areas of a substrate to be textured, as well as entire surfaces. A variety of techniques of laser processing to form a textured region are contemplated, and any technique capable of forming such a region should be considered to be within the present scope. Laser treatment or processing can allow, among other things, enhanced absorption properties and thus increased electromagnetic radiation focusing and detection.

In one aspect, for example, a target region of the substrate to be textured can be irradiated with laser radiation to form a textured region. Examples of such processing have been described in further detail in U.S. Pat. Nos. 7,057,256, 7,354,792 and 7,442,629, which are incorporated herein by reference in their entireties. Briefly, a surface of a substrate material is irradiated with laser radiation to form a textured or surface modified region. Such laser processing can occur with or without a dopant material. In those aspects whereby a dopant is used, the laser can passed through a dopant carrier and onto the substrate surface. In this way, dopant from the dopant carrier is introduced into the target region of the substrate material. Such a region incorporated into a substrate material can have various benefits in accordance with aspects of the present disclosure. For example, the textured region typically has a textured surface that increases the surface area and increases the probability of radiation absorption. In one aspect, such a textured region is a substantially textured surface including micron-sized and/or nano-sized surface features that have been generated by the laser texturing. In another aspect, irradiating the surface of a substrate material includes exposing the laser radiation to a dopant such that irradiation incorporates the dopant into the substrate. Various dopant materials are known in the art, and are discussed in more detail herein.

Thus the surface of the substrate at the target region is thus chemically and/or structurally altered by the laser treatment, which may, in some aspects, result in the formation of surface features appearing as structures or patterned areas on the surface and, if a dopant is used, the incorporation of such dopants into the substrate material. In some aspects, the features or structures can be on the order of 50 nm to 20 μm in size and can assist in the absorption of electromagnetic radiation. In other words, the textured surface can increase the probability of incident radiation being absorbed.

The type of laser radiation used to surface modify a material can vary depending on the material and the intended modification. Any laser radiation known in the art can be used with the devices and methods of the present disclosure. There are a number of laser characteristics, however, that can affect the surface modification process and/or the resulting product including, but not limited to, the wavelength of the laser radiation, pulse width, pulse fluence, pulse frequency, polarization, laser propagation direction relative to the semiconductor material, etc. In one aspect, a laser can be configured to provide pulsatile lasing of a material. A short-pulsed laser is one capable of producing femtosecond, picosecond, and/or nanosecond pulse durations. Laser pulses can have a central wavelength in a range of about from about 10 nm to about 8 μm, and more specifically from about 200 nm to about 1200 nm. The pulse width of the laser radiation can be in a range of from about tens of femtoseconds to about hundreds of nanoseconds. In one aspect, laser pulse widths can be in the range of from about 50 femtoseconds to about 50 picoseconds. In another aspect, laser pulse widths can be in the range of from about 50 picoseconds to 100 nanoseconds. In another aspect, laser pulse widths are in the range of from about 50 to 500 femtoseconds.

The number of laser pulses irradiating a target region can be in a range of from about 1 to about 2000. In one aspect, the number of laser pulses irradiating a target region can be from about 2 to about 1000. Further, the repetition rate or frequency of the pulses can be selected to be in a range of from about 10 Hz to about 10 μHz, or in a range of from about 1 kHz to about 1 MHz, or in a range from about 10 Hz to about 1 kHz. Moreover, the fluence of each laser pulse can be in a range of from about 1 kJ/m² to about 20 kJ/m², or in a range of from about 3 kJ/m² to about 8 kJ/m².

A variety of dopant materials are contemplated for both the formation of doped regions in the semiconductor layer and for doping of the textured region, and any dopant that can be used in such processes to modify a material is considered to be within the present scope. It should be noted that the particular dopant utilized can vary depending on the material being doped, as well as the intended use of the resulting material.

A dopant can be either a charge donating or a charge accepting dopant species. More specifically, an electron donating or a hole donating species can cause a region to become more positive or negative in polarity as compared to the substrate upon which the rests. In one aspect, for example, the doped region can be p-doped. In another aspect the doped region can be n-doped.

In one aspect, non-limiting examples of dopant materials can include S, F, B, P, N, As, Se, Te, Ge, Ar, Ga, In, Sb, and combinations thereof. It should be noted that the scope of dopant materials should include, not only the dopant materials themselves, but also materials in forms that deliver such dopants (i.e. dopant carriers). For example, S dopant materials includes not only S, but also any material capable being used to dope S into the target region, such as, for example, H₂S, SF₆, SO₂, and the like, including combinations thereof. In one specific aspect, the dopant can be S. Sulfur can be present at an ion dosage level of from about 5×10¹⁴ to about 3×10²⁰ ions/cm². Non-limiting examples of fluorine-containing compounds can include ClF₃, PF₅, F₂ SF₆, BF₃, GeF₄, WF₆, SiF₄, HF, CF₄, CHF₃, CH₂F₂, CH₃F, C₂F₆, C₂HF₅, C₃F₈, C₄F₈, NF₃, and the like, including combinations thereof. Non-limiting examples of boron-containing compounds can include B(CH₃)₃, BF₃, BCl₃, BN, C₂B₁₀H₁₂, borosilica, B₂H₆, and the like, combinations thereof. Non-limiting examples of phosphorous-containing compounds can include PF₅, PH₃, POCl₃, P₂O₅, and the like, including combinations thereof. Non-limiting examples of chlorine-containing compounds can include Cl₂, SiH₂Cl₂, HCl, SiCl₄, and the like, including combinations thereof Dopants can also include arsenic-containing compounds such as AsH₃ and the like, as well as antimony-containing compounds. Additionally, dopant materials can include mixtures or combinations across dopant groups, i.e. a sulfur-containing compound mixed with a chlorine-containing compound. In one aspect, the dopant material can have a density that is greater than air. In one specific aspect, the dopant material can include Se, H₂S, SF₆, or mixtures thereof. In yet another specific aspect, the dopant can be SF₆ and can have a predetermined concentration range of about 5.0×10⁻⁸ mol/cm³ to about 5.0×10⁻⁴ mol/cm³. As one non-limiting example, SF₆ gas is a good carrier for the incorporation of sulfur into a substrate via a laser process without significant adverse effects on the material. Additionally, it is noted that dopants can also be liquid solutions of n-type or p-type dopant materials dissolved in a solution such as water, alcohol, or an acid or basic solution. Dopants can also be solid materials applied as a powder or as a suspension dried onto the wafer.

In one aspect, the textured region can be doped with a dopant to form an electrical back surface field (EBSF). The EBSF impedes the movement of minority carriers from reaching the textured region, thus keeping such carriers away from potential recombination sites near the interface. Similarly, dark current generation can also be minimized by pinning the interface generation states at certain band energy states through band structure optimization so that the dark carrier generation mechanism is suppressed. Band structure optimization can be achieved by using a variety of methods. It should be noted that any method that forms an electrical field near or within the textured region can be used. Non-limiting examples of such methods can include shifting the Fermi level energy, bending the minority carrier band, inserting a material with a different bandgap, and the like, including combinations thereof.

In one aspect, for example, the band structure optimization can be realized by modifying the interface doping concentration. For example, for a p-type laser textured region, a more heavily p-doped layer that partially overlaps with the laser modified interface can be used. The conduction band thus bends toward the higher energy direction when reaching towards the more p-doped layer, and hence the laser modified interface. One specific aspect is a heavily doped p++ layer that partially overlaps with the laser modified interface layer in a p-epi substrate where both the p++ layer and the modified interface layer sit between the bottom of an epitaxial device layer and the top of a carrier wafer.

As such, in one aspect, the EBSF has been doped by a technique such as, without limitation, laser doping, ion implanting, diffusion doping, in situ doping, and the like, including combinations thereof. In another aspect, the textured region or the EBSF has a higher dopant concentration than the semiconductor layer. In yet another aspect, the dopant has the same polarity as the semiconductor layer. Various dopants for use in generating an EBSF are contemplated. Non-limiting examples include boron, indium, gallium, arsenic, antimony, phosphorus, and the like, including combinations thereof It should also be noted that an EBSF can be produced in the semiconductor layer, the dielectric layer, or the semiconductor substrate. In one aspect, for example, semiconductor layer or the semiconductor substrate is doped with a dopant to form an electrical back surface field, where the EBSF is distinct from the textured region.

In another aspect, the band structure optimization can be realized by forming a heterojunction along a modified semiconductor interface. For example, a layer of amorphous silicon can be deposited on the textured region interface, thus forming a heterojunction that bends the minority carrier band towards the desired energy direction.

The dielectric layer can be made from a variety of materials, and such materials can vary depending on the device design and desired characteristics. One use for such a layer involves the coupling of the semiconductor layer to the semiconductor substrate. In some cases, wafer bonding can be used as a coupling technique. The dielectric layer can thus facilitate the attachment of these materials together, as has been described. The dielectric layer can be associated with the semiconductor layer, the semiconductor substrate, or both the semiconductor layer and the semiconductor substrate prior to bonding. In those aspects having a dielectric layer associated with both materials, the dielectric layers can be bonded directly together, or in some cases, bonded together with an intervening textured region. Additionally, in some aspects a textured region can be formed on one or more dielectric layers. In some aspects, a dielectric layer can be bonded to a semiconductor material such as, for example, polysilicon. In other aspects, the semiconductor layer and the semiconductor substrate can be bonded together without an intervening dielectric layer.

Non-limiting examples of dielectric layer materials can include oxides, nitrides, oxynitrides, and the like, including combinations thereof. In one specific aspect, the dielectric layer includes an oxide. In another aspect, the dielectric layer includes a buried oxide. Additionally, the dielectric layer can be of various thicknesses. In one aspect, for example, the dielectric layer has a thickness of from about 100 nm to about 4 microns. In another aspect, the dielectric layer has a thickness of from about 500 nm to about 2 microns. In yet another aspect, the dielectric layer has a thickness of from about 500 nm to about 1000 microns.

The devices according to aspects of the present disclosure can additionally include one or more reflecting regions. In one aspect, as is shown in FIG. 3, a photosensitive semiconductor device 30 can include a semiconductor substrate 32 and a semiconductor layer 34 coupled to the semiconductor substrate. The device also includes at least one textured region 36 located or coupled between the semiconductor substrate and the semiconductor layer, and at least one dielectric layer 38 coupled between the semiconductor substrate and the semiconductor layer. A reflecting region 39 is coupled to the semiconductor substrate, and positioned to interact with electromagnetic radiation. The reflecting region can be separated from the textured region by a dielectric layer as is shown, or the reflecting region can be associated directly with the textured region without an intervening dielectric layer. The reflecting region can be deposited over the entire interface between the semiconductor substrate and the next adjacent layer, or only over a portion of the interface. In some aspects, the reflecting region can be deposited over a larger area of the device compared to the textured region. The reflecting region can be positioned to reflect electromagnetic radiation that has passed through the texture region back through the textured region toward the semiconductor layer. In other words, as electromagnetic radiation passes through the semiconductor layer, a portion that is not absorbed contacts the textured region. Of that portion that contacts the textured region, a smaller portion may pass though the textured region to strike the reflecting region and be reflected back through the textured region toward the semiconductor layer.

A variety of reflective materials can be utilized in constructing the reflecting region, and any such material capable of incorporation into a photosensitive device is considered to be within the present scope. Non-limiting examples of such materials include a Bragg reflector, a metal reflector, a metal reflector over a dielectric material, a transparent conductive oxide such as zinc oxide, indium oxide, or tin oxide, and the like, including combinations thereof. Non-limiting examples of metal reflector materials can include silver, aluminum, gold, platinum, reflective metal nitrides, reflective metal oxides, and the like, including combinations thereof. In one aspect, a dielectric material can be coupled to the reflecting region along the side facing the textured region. In one specific aspect, the dielectric material can include an oxide layer and the reflecting region can include a metal layer. The surface of the metal layer on an oxide acts as a mirror-like reflector for the incident electromagnetic radiation from the backside.

Additionally, the textured surface of a metal on a roughened oxide can act as a diffusive scattering site for the incident electromagnetic radiation and also as a mirror-like reflector. Other aspects can utilize porous materials for the texturing. Porous polysilicon, for example, can be oxidized or oxide deposited and a reflective region such as a metal reflector can be associated therewith to provide a scattering and reflecting surface. In another aspect, aluminum can be subjected to anodic oxidation to provide porous aluminum oxide, a high dielectric constant insulator. This insulator can be coated with aluminum or other metals to provide a scattering and reflecting surface.

In one specific aspect, a reflective region can include a transparent conductive oxide, an oxide, and a metal layer. The transparent oxide can be textured and a metal reflector deposited thereupon. The textured surface of the metal on a roughened transparent conductive oxide can act as a diffusive scattering site for the incident electromagnetic radiation.

In another specific aspect, a Bragg reflector can be utilized as a reflective region. A Bragg reflector is a structure formed from multiple layers of alternating materials with varying refractive indexes, or by a periodic variation of some characteristic (e.g. height) of a dielectric waveguide, resulting in periodic variation in the effective refractive index in the guide. Each layer boundary causes a partial reflection of an optical wave. For waves whose wavelength is close to four times the optical thickness of the layers, the many reflections combine with constructive interference, and the layers act as a high-quality reflector. Thus the coherent super-positioning of reflected and transmitted light from multiple interfaces in the structure interfere so as to provide the desired reflective, transmissive, and absorptive behavior. In one aspect, the Bragg reflector layers can be alternating layers of silicon dioxide and silicon. Because of the high refractive index difference between silicon and silicon dioxide, and the thickness of these layers, this structure can be fairly low loss even in regions where bulk silicon absorbs appreciably. Additionally, because of the large refractive index difference, the optical thickness of the entire layer set can be thinner, resulting in a broader-band behavior and fewer fabrications steps.

Additional scattering can be provided by positioning a textured forward scattering layer on the side of the device that receives incident electromagnetic radiation. These forward scattering layers can be, without limitation, textured oxides or polysilicon without a reflector.

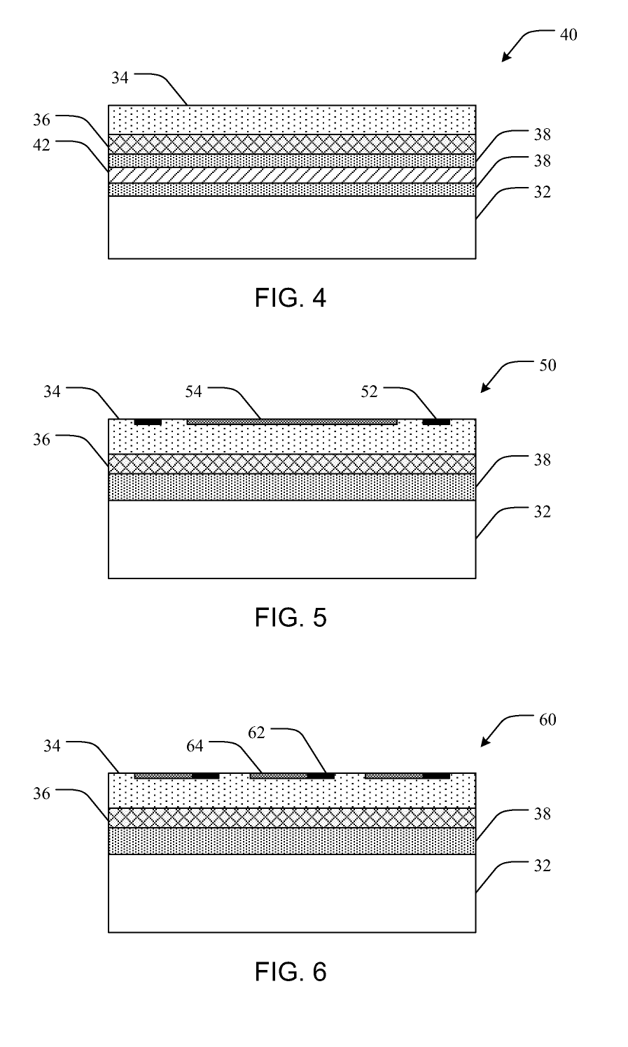

In another aspect, as is shown in FIG. 4, a photosensitive semiconductor device 40 can also include a polysilicon layer 42 disposes between multiple dielectric layers 38. It should be noted that all reference numbers in FIG. 4 that have been reused from previous figures denote the same or similar materials and/or structures whether or not further description is provided. The addition of the polysilicon layer can provide various improvements in manufacturing in some cases. For example, a rough surface of a textured region can be challenging to wafer bond. By depositing a thin dielectric layer followed by a thick polysilicon layer it can be possible to create a surface that can be polished. Thus, the polysilicon layer can be planarized and polished until smooth, and the resulting surface can be wafer bonded to the dielectric layer on the opposing material, e.g. the semiconductor substrate if the polysilicon is deposited on the semiconductor layer structure. It is also contemplated that such a process can be performed with only one dielectric layer or even without any dielectric layers being present. In another aspect, the polysilicon layer can be doped with a dopant. In yet another aspect, the polysilicon layer can be a monosilicon layer. In one specific aspect, the polysilicon layer is a monosilicon layer and the semiconductor layer is an epitaxial layer that has been etched from the backside to form the textured region.

In another aspect, as is shown in FIG. 5, a photodiode 50 having enhanced light detection performance is provided. The photodiode includes contacts 52 and a photodiode junction 54 formed on the semiconductor layer 34. In another aspect, as is shown in FIG. 6, a CMOS image sensor having improved light detection performance is provided. The CMOS image sensor includes photodiode junctions 64 and circuitry 62 formed on the semiconductor layer 34. It should be noted that all reference numbers in FIGS. 5 and 6 that have been reused from previous figures denote the same or similar materials and/or structures whether or not further description is provided. In this way, the textured region 36 can be introduced into fabrication process at the start of the flow, at a lower cost and lower technical risk approach. Because the textured region is buried within the semiconductor materials at an early stage in the flow, the textured region can be protected from contamination during the further fabrication of the device. Additionally, potentially proprietary details such as the specific architecture of the texture region can be protected from view during the later stages of fabrication. This method could further include a step of removing the semiconductor substrate. It is understood that once the semiconductor device is formed the semiconductor substrate may no longer be necessary in some cases. In this way the semiconductor device can be mounted on various substrates as necessary for specific applications.

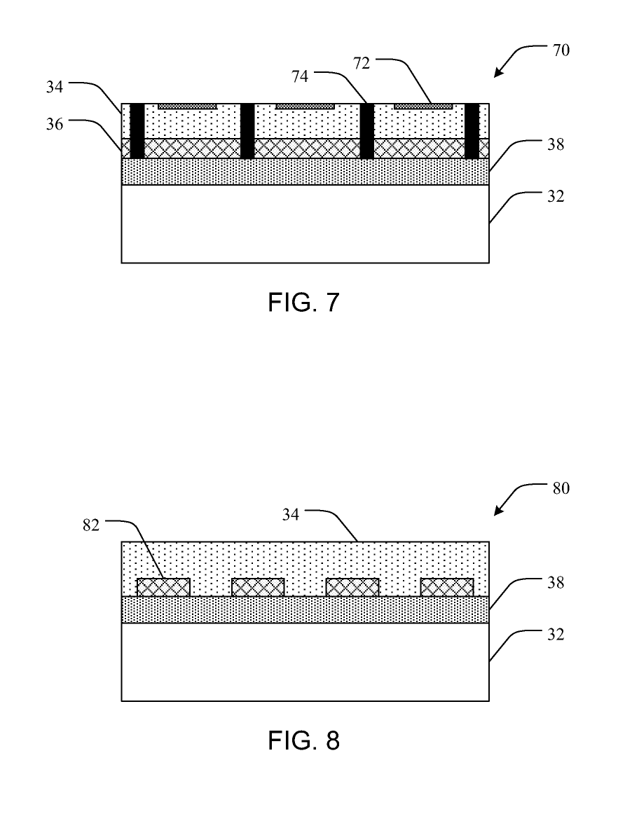

In one aspect, isolation features can be utilized in order to isolate various portions of the device from one another. For example, in one aspect a semiconductor device can include a plurality of isolation features in at least the semiconductor layer that function to isolate each photodetector in an array of photodetectors from one another. The isolation features isolate each photodetector electrically, optically, or both electrically and optically. Isolation features can thus maintain uniformity across an array by reducing optical and electrical crosstalk between the photodetectors. FIG. 7 shows a semiconductor device 70 having an array of photodetectors 72. It should be noted that all reference numbers in FIG. 7 that have been reused from previous figures denote the same or similar materials and/or structures whether or not further description is provided. The photodetectors are separated by a plurality of isolation features, in this case extending through the semiconductor layer 34 and the textured region 36. In one aspect, the isolation features extend through the semiconductor layer but not through the textured region. In another aspect, the isolation features extend beyond the textured region and into the dielectric layer or even into the semiconductor substrate. In some aspects, other structures such as polysilicon layers and reflective regions can contain isolation features. Accordingly, the isolation features can be deep or shallow, depending on the desired configuration of the device.

Isolation features can be made from various materials, including, without limitation, dielectric materials, reflective materials, conductive materials, light diffusing features, voids, and the like, including combinations thereof. Conductive materials used to fill the isolation feature etches or voids can be passivated in order to maintain electrical isolation. In other aspects, conductive materials can be utilized as vias. The isolation can be fabricated at the substrate level prior to fabrication of circuitry, the detector device, or the imaging array. In one aspect, voids can be created and either left as voids or filled with such materials to form the isolation features. For example, a layer surface can be photolithographically patterned and vertically etched to a desired depth (e.g. from the device surface of the semiconductor layer to the dielectric layer). Dielectric material can then be deposited conformally on surfaces within the etch until filled with the dielectric or other material. Any dielectric material remaining on the device surface of the semiconductor layer can be removed by chemical etching and/or mechanical polishing. As has been described, the isolation feature does not need to fully bisect the semiconductor structure, but rather only a portion can be isolated; this is known as shallow trench isolation as opposed to deep trench isolation.

Additionally, isolation features regions can be configured to reflect incident electromagnetic radiation until it is absorbed, thereby increase the effective absorption length of the device. In other aspects, the sides of isolation features can be doped. In some aspects, a doped isolation feature can form an electrical surface field, similar to an electrical back surface field as has been described. The isolation features can be formed before or after bonding of the semiconductor substrate to the semiconductor layer. Furthermore, the isolation features can be formed from either side of the semiconductor layer or from either side of the semiconductor substrate, depending on the depth and extent of the features.

In some aspects, the textured region can be arranged in a discontinuous pattern. As is shown in FIG. 8, for example, a semiconductor device 80 can have a discontinuous textured region 82. It should be noted that all reference numbers in FIG. 8 that have been reused from previous figures denote the same or similar materials and/or structures whether or not further description is provided. Such a discontinuous pattern may correspond to structures elsewhere in the device, such as the spatial pattern of an array of photo detectors on the device surface (not shown).

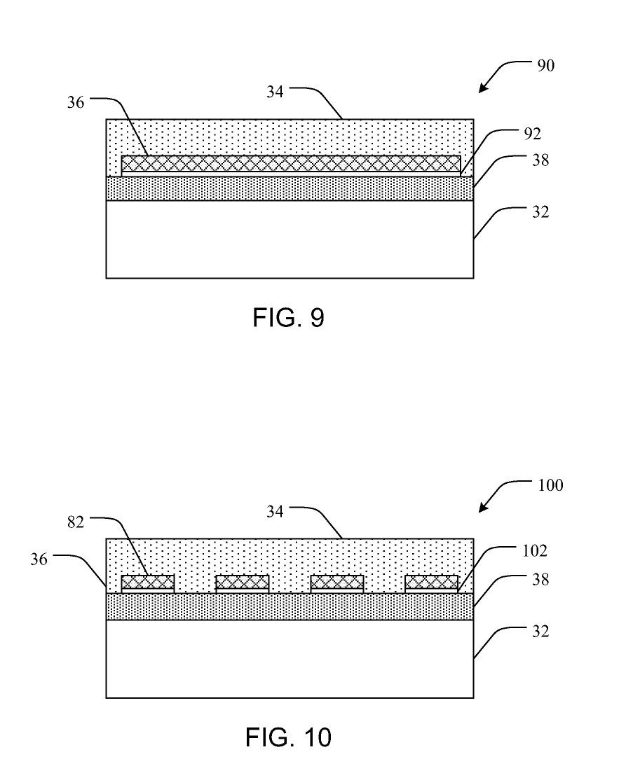

In other aspects, one or more cavities can be disposed in the semiconductor device and associated with the textured region or regions. As is shown in FIG. 9, for example, a semiconductor device 90 can include a cavity region 92 associated with the textured region 36. The cavity region can enhance the functionality of the textured region, and can be particularly effective when optically coupled to a reflective region, whether the reflective region is on the near side or the far side of the dielectric layer 38. FIG. 10 shows a semiconductor device 100 having a plurality of cavity regions 102 arranged in a discontinuous pattern to correspond with the discontinuous pattern of the textured region 82. The cavity regions shown in FIGS. 9 and 10 can be formed prior to wafer bonding or following wafer bonding. If a cavity region is formed following wafer bonding, etching through the semiconductor substrate 32 may be required, following which the etch cavity can be partially filled. Additionally, a cavity region can be formed before or after formation of the textured region. In those aspects whereby a cavity region is formed after formation of the textured region, the intervening material would be etched until reaching the textured region. In those aspects whereby a cavity region is formed prior to formation of the textured region, an etch can be formed into the semiconductor layer 34 and the textured region can be formed thereon through the etch cavity. The formation of the textured region in this manner can be accomplished prior to wafer bonding or following wafer bonding by etching through the semiconductor substrate. It should be noted that all reference numbers in FIGS. 9 and 10 that have been reused from previous figures denote the same or similar materials and/or structures whether or not further description is provided.

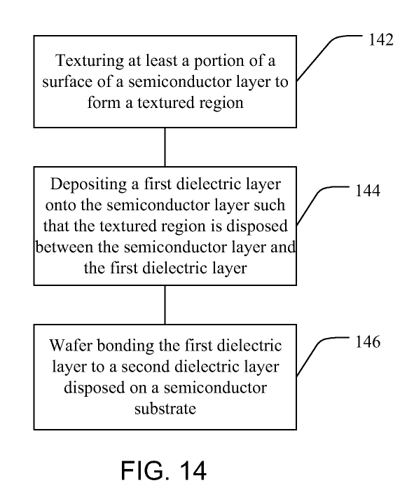

The present disclosure additionally provides various methods. In one aspect, as is shown in FIG. 14, for example, a method of making a semiconductor device can include texturing at least a portion of a surface of a semiconductor layer to form a textured region 142, depositing a first dielectric layer onto the semiconductor layer such that the textured region is disposed between the semiconductor layer and the first dielectric layer 144, and wafer bonding the first dielectric layer to a second dielectric layer disposed on a semiconductor substrate 146. In another aspect, the textured region is protected from contamination during further manufacturing processes by the semiconductor layer and the semiconductor substrate.

In another aspect, a method of making a semiconductor device can include laser texturing at least a portion of a surface of a semiconductor layer to form a textured region, depositing a first dielectric layer onto the semiconductor layer such that the textured region is disposed between the semiconductor layer and the first dielectric layer, and wafer bonding the first dielectric layer to a second dielectric layer disposed on a semiconductor substrate.

In yet another aspect, a method of making a semiconductor device can include wet etch texturing at least a portion of a surface of a semiconductor layer to form a textured region, depositing a first dielectric layer onto the semiconductor layer such that the textured region is disposed between the semiconductor layer and the first dielectric layer, and wafer bonding the first dielectric layer to a second dielectric layer disposed on a semiconductor substrate.

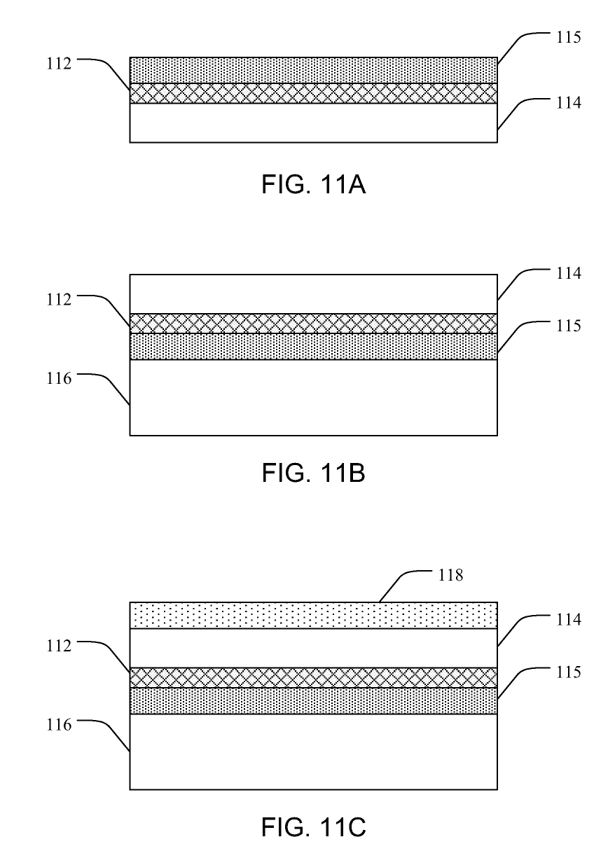

In one specific aspect, FIGS. 11A-C show one method of manufacturing a semiconductor device. As is shown in FIG. 11A, a semiconductor material 114 can be textured to create a textured region 112, and a dielectric layer 115 can be deposited over the textured region. In one aspect, the textured region can be formed by laser processing the semiconductor material. In another aspect, the textured region can be formed by wet etching the semiconductor material. The dielectric layer can then be polished until smooth with a process such as CMP processing. The resulting structure can then be wafer bonded to a semiconductor substrate 116, as is shown rotated 180° in FIG. 11B, with the polished surface of the dielectric layer being bonded to the semiconductor substrate. The dielectric layer can be bonded directly to the semiconductor substrate, or to a second dielectric layer formed on the semiconductor substrate (not shown). After wafer bonding, the semiconductor material can be polished to a specified thickness. In another aspect, an epitaxially grown semiconductor layer 118 can be grown on the polished surface of the semiconductor material to generate a low defect device region as shown in FIG. 11C.

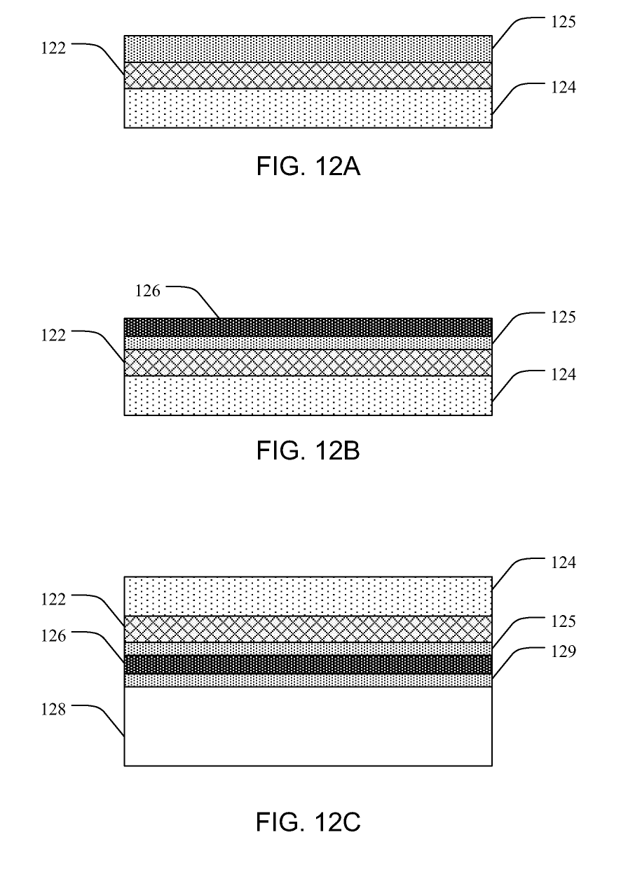

In another aspect, FIGS. 12A-C show another method of manufacturing a semiconductor device. As is shown in FIG. 12A, a semiconductor material 124 can be textured to create a textured region 122, and a dielectric layer 125 can be deposited over the textured region. In one aspect, the semiconductor material can be an epitaxially grown semiconductor material. The dielectric layer can then be polished and a polysilicon layer 126 can be deposited thereupon, as is shown in FIG. 12B. In an alternative aspect, the polysilicon layer can be formed directly on the textured region without an intervening dielectric layer (not shown). The polysilicon layer can then be polished and wafer bonded to a semiconductor substrate 126, as is shown rotated 180° in FIG. 12C. The polysilicon layer can be bonded directly to the semiconductor substrate, or to a second dielectric layer 129 formed on the semiconductor substrate. After wafer bonding, the semiconductor material can be polished to a specified thickness.

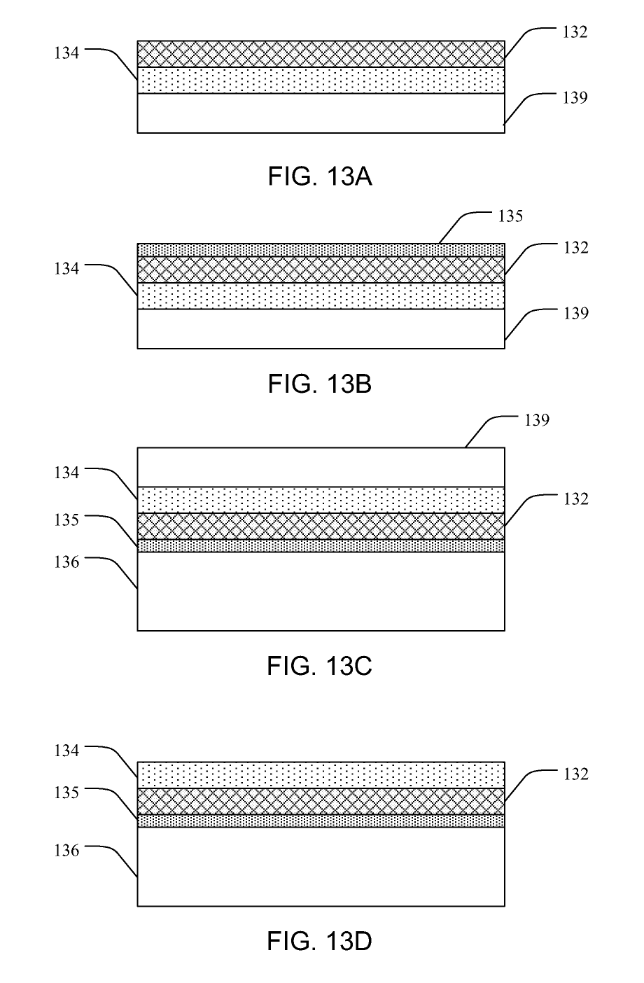

In another aspect, FIGS. 13A-D show another method of manufacturing a semiconductor device. As is shown in FIG. 13A, a semiconductor layer 134 can be epitaxially grown on a temporary semiconductor support 139. The epitaxially grown semiconductor layer is textured to create a textured region 132, and a dielectric layer 135 is deposited over the textured region as is shown in FIG. 13B. Following polishing, the dielectric layer is wafer bonded to a semiconductor substrate 136, as is shown rotated 180° in FIG. 13C. The dielectric layer can be bonded directly to the semiconductor substrate, or to a second dielectric layer formed on the semiconductor substrate (not shown). The temporary semiconductor support can then be removed from the epitaxially grown semiconductor layer. This can be accomplished by any known process, such as wafer splitting, CMP processing, etc. The exposed epitaxial semiconductor layer can be further polished and thinned to produce a desired surface for further device deposition. In this manner semiconductor materials used to grow the epitaxial layer can be removed, leaving a higher quality surface with fewer crystal defects and dislocations.

Of course, it is to be understood that the above-described arrangements are only illustrative of the application of the principles of the present disclosure. Numerous modifications and alternative arrangements may be devised by those skilled in the art without departing from the spirit and scope of the present disclosure and the appended claims are intended to cover such modifications and arrangements. Thus, while the present disclosure has been described above with particularity and detail in connection with what is presently deemed to be the most practical embodiments of the disclosure, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A semiconductor device, comprising:
a semiconductor substrate;
a semiconductor layer coupled to the semiconductor substrate, the semiconductor layer having a device surface opposite the semiconductor substrate; and
at least one textured region coupled between the semiconductor substrate and the semiconductor layer.

2. The device of claim 1, further comprising at least one dielectric layer coupled between the semiconductor substrate and the semiconductor layer.

3. The device of claim 2, wherein the semiconductor layer is an epitaxially grown semiconductor layer.

4. The device of claim 2, wherein the semiconductor layer is a silicon layer.

5. The device of claim 2, further comprising a secondary semiconductor layer disposed between the textured region and the semiconductor layer.

6. The device of claim 2, wherein the dielectric layer is coupled between the semiconductor substrate and the textured region, and wherein the textured region is disposed between the dielectric layer and the semiconductor layer.

7. The device of claim 6, further comprising a reflective region disposed between the semiconductor substrate and the textured region.

8. The device of claim 6, wherein the textured region is coupled directly to the semiconductor layer.

9. The device of claim 6, further comprising a secondary semiconductor layer disposed between the textured region and the semiconductor layer.

10. The device of claim 6, further comprising at least one cavity region disposed between the textured region and the dielectric layer.

11. The device of claim 2, further comprising a polysilicon layer directly coupled to the dielectric layer.

12. The device of claim 11, wherein the polysilicon layer is disposed between multiple dielectric layers.

13. The device of claim 2, wherein the textured region is disposed between the semiconductor substrate and the dielectric layer, and wherein the dielectric layer is disposed between the textured region and the semiconductor layer.

14. The device of claim 2, wherein the textured region is doped with a dopant to form an electrical back surface field.

15. The device of claim 14, wherein the electrical back surface field has been doped by a technique selected from the group consisting of laser doping, ion implanting, diffusion doping, in situ doping, and combinations thereof.

16. The device of claim 15, wherein the textured region has a higher dopant concentration than the semiconductor layer.

17. The device of claim 15, wherein the dopant has the same polarity as the semiconductor layer.

18. The device of claim 15, wherein the dopant is a member selected from the group consisting of boron, indium, gallium, arsenic, antimony, phosphorus, and combinations thereof.

19. The device of claim 2, wherein the semiconductor layer is doped with a dopant to form an electrical back surface field, and wherein the electrical back surface field is distinct from the textured region.

20. The device of claim 2, further comprising at least one photodiode optically active region disposed on the device surface.

21. The device of claim 2, wherein the photodiode optically active region comprises a doped region.

22. The device of claim 2, wherein the device forms at least one photodetector.

23. The device of claim 22, wherein the at least one photodetector is a plurality of photodetectors arranged in an array.

24. The device of claim 23, wherein the textured region is arranged in a discontinuous pattern that corresponds spatially to the array of photodetectors.

25. The device of claim 23, further comprising a plurality of isolation features in at least the semiconductor layer to isolate each photodetector in the array of photodetectors, wherein the isolation features isolate each photodetector electrically, optically, or both electrically and optically.

26. The device of claim 23, further comprising at least one optical lens associated with the at least one photodetector.

27. The device of claim 23, further comprising at least one color filter associated with the at least one photodetector.

28. A method of making a semiconductor device, comprising:
texturing at least a portion of a surface of a semiconductor layer to form a textured region;
depositing a first dielectric layer onto the semiconductor layer such that the textured region is disposed between the semiconductor layer and the first dielectric layer; and
wafer bonding the first dielectric layer to a second dielectric layer disposed on a semiconductor substrate.

29. The method of claim 28, wherein the semiconductor layer is an epitaxially grown semiconductor layer.

30. The method of claim 29, wherein texturing at least a portion of a surface of a semiconductor layer to form a textured region further includes:
forming the epitaxially grown semiconductor layer on a growth substrate; and
texturing at least a portion of a surface of the epitaxially grown semiconductor layer to form a textured region.

31. The method of claim 30, further comprising removing the growth substrate to expose the epitaxially grown semiconductor layer.

32. The method of claim 28, further comprising forming an epitaxially grown semiconductor layer on the semiconductor layer on an opposite side from the textured region.

33. The method of claim 28, wherein wafer bonding further includes:
depositing a polysilicon layer on the first dielectric layer; and
bonding the polysilicon layer between the first dielectric layer and the second dielectric layer.

34. The method of claim 33, further comprising doping at least a portion of the polysilicon layer.

35. The method of claim 28, wherein texturing at least a portion of a surface of the semiconductor layer to form the textured region further includes:
forming an opening in the semiconductor substrate, the second dielectric layer, and the first dielectric layer to expose a portion of the semiconductor layer; and
texturing at least a portion of the exposed portion of the semiconductor layer to form the textured region.

36. The method of claim 28, wherein texturing includes a technique selected from the group consisting of plasma etching, reactive ion etching, porous silicon etching, lasing, chemical etching, nanoimprinting, material deposition, selective epitaxial growth, and combinations thereof.

37. The method of claim 28, wherein texturing includes lasing.

38. A method of protecting a textured region from contamination during manufacture of a semiconductor device, comprising:
texturing at least a portion of a surface of a semiconductor layer to form a textured region;
depositing a first dielectric layer onto the semiconductor layer such that the textured region is disposed between the semiconductor layer and the dielectric layer; and
wafer bonding the first dielectric layer to a second dielectric layer disposed on a semiconductor substrate, wherein the textured region is protected from contamination during further manufacturing processes by the semiconductor layer and the semiconductor substrate.
